(19) United States
(12) Patent Application Publication
(10) Pub. No.: US 2023/0375277 A1
(43) Pub. Date: Nov. 23, 2023

(54) PROCESS AND SYSTEM FOR HEAT EXCHANGE PROCESS

(71) Applicants: UNIVERSITY OF NORTH TEXAS, Dallas, TX (US); THE TEXAS A&M UNIVERSITY SYSTEM, College Station, TX (US); THE UNIVERSITY OF AKRON, Akron, OH (US)

(72) Inventors: Vish PRASAD, Dallas, TX (US); Zihao ZHANG, Dallas, TX (US); Debjyoti BANERJEE, College Station, TX (US); Guo-Xiang WANG, Akron, OH (US); Hamid SADAT, Dallas, TX (US); Huseyin BOSTANCI, Dallas, TX (US); Laura ALMARA, Dallas, TX (US)

(21) Appl. No.: 18/320,727

(22) Filed: May 19, 2023

Related U.S. Application Data
(60) Provisional application No. 63/344,429, filed on May 20, 2022.

(51) Int. Cl. F28D 9/00; F28F 23/00

(52) U.S. Cl. CPC F28D 9/0081; F28F 23/00; B33Y 80/00

(57) ABSTRACT

A heat exchange process includes exchanging heat using a working fluid, where the working fluid comprises a mixture of two or more supercritical fluids, and the mixture is adapted to meet requirements of a heat dissipation temperature from extremely low to very high temperatures. The two or more supercritical fluids can be in a supercritical gaseous state.

### CROSS-REFERENCES TO RELATED APPLICATIONS

This application claims the benefit of U.S. Provisional Application No. 63/344,429, filed on Mar. 20, 2022, and entitled “Method and Systems using a Mixture of Supercritical Fluid Prepared Selectively for Heat Dissipation at Very-low to Very-high Temperatures and Pipeline Transport,” which is incorporated herein by reference in its entirety for all purposes.

### STATEMENT REGARDING FEDERALLY SPONSORED RESEARCH OR DEVELOPMENT

This invention was made with government support under Grant 2231393 awarded by the National Science Foundation. The government has certain rights in this invention.

### BACKGROUND

Five states of fluid may be used in operations: (i) liquid, (ii) chilled liquid temperature (T) less than temperature critical (T_{c}), pressure (P) greater than pressure critical (P_{c}), (iii) two-phase liquid-vapor, (iv) gas T greater than T_{cr}, P less than P_{cr}, and (v) dense phase (T greater than T_{c}, P greater than P_{cr}), where P_{cr} is the pressure cricondenbar, T_{cr} is the temperature cricondentherm. The dense phase properties of gas, such as methane and a selected natural gas composition has been discussed in the range of −120° C. less than T less than −60° C., P less than 6 MPa and −100° C. less than or equal T less than or equal 125° C., P less than or equal 17 MPa, respectively; indeed, selected pressures and temperatures ranged from liquid to dense phase conditions.

However, there have been shortcomings to fully understand the dense phase. The dense phase can be beyond T_{c} in the case of a single gas and can be beyond T_{c} and T_{cr} for a gas mixture in the supercritical regime. In fact, supercritical (SC) conditions are contemplated without addressing the complexities of the SC state. Note that to avoid dew formation (phase change to liquid), the temperature of the natural gas under dense phase (referred to even as the “fourth state”) must be above T_{cr} which is generally greater than T_{c} for a natural gas. A challenge then arises because of the existence of anomalous state in the vicinity of the critical point, particularly on the supercritical side. Indeed, the initial belief that beyond the critical point the liquid and vapor are indistinguishable has already been belied. Thus, there is a shortcoming of properly identifying a supercritical state for use of two or more supercritical fluids as a heat transfer fluid, and a thermal energy storage fluid. Although the phenomenon of variation in critical temperature and also critical pressure of a mixture based on the fraction of fluids has been reported, its application as a heat transfer and/or thermal energy storage fluid has never been demonstrated.

### SUMMARY

In some embodiments, a heat exchange process comprises exchanging heat using a working fluid. The working fluid comprises a mixture of two or more supercritical fluids, and the mixture adapted to meet requirements of a heat dissipation temperature from extremely low to very high temperatures.

In some embodiments, a system comprises a heat exchanger, a working fluid, wherein the working fluid is a mixture of supercritical fluids, and a pumped loop. The system is configured to circulate the working fluid in the pumped loop to gain heat from one zone and to dissipate the heat to ambient.

These and other features will be more clearly understood from the following detailed description taken in conjunction with the accompanying drawings and claims.

### BRIEF DESCRIPTION OF THE DRAWINGS

For a more complete understanding of the present disclosure and the advantages thereof, reference is now made to the following brief description, taken in connection with the accompanying drawings and detailed description, wherein like reference numerals represent like parts.

FIG. 1 is a depiction of a Table 1 with parts (a), (b), and (c) for thermophysical properties, heat transfer rate, and pressure loss/work required for fully-developed flow of carbon dioxide through an isothermally-heated circular pipe at various pressures under subcritical and supercritical conditions.

FIG. 2 is a depiction of a Table 2a for critical points of select fluids with a critical temperature T_{c} less than 25 degrees Celsius (25° C.).

FIG. 3 is a depiction of a Table 2b for critical points of select fluids with a critical temperature T_{c} more than 25° C.

FIG. 4 is a depiction of a Table 3 of critical points, cricondenbars, cricondentherms for the mixture of carbon dioxide and argon.

FIG. 5 is a depiction of a Table 4 of critical points for the mixture of carbon dioxide and nitrogen.

FIG. 6 is a depiction of a Table 5 of critical points, cricondenbars, and cricondentherms for the mixture of carbon dioxide and refrigerant, R134a.

FIG. 7 is a schematic diagram of an embodiment of a heat exchanger and a heat dissipater with a loop of working fluid passed therebetween.

FIG. 8 is a schematic diagram of an embodiment of a heat exchanger and a radiation device with a loop of working fluid passed therebetween.

FIG. 9 is a schematic diagram of an embodiment of a heat exchanger and a cold plate with a loop of working fluid passed therebetween.

FIG. 10 is a schematic diagram of an embodiment of a cooler and a heat dissipater with a loop of working fluid passed therebetween.

FIG. 11 is a graphical depiction of specific heat, Cₚ, of carbon dioxide CO₂ with a critical pressure Pc=7.38 MPa and a critical temperature T_{c}=304.13 K, 30.98° C.

FIG. 12 is a graphical depiction of density, ρ, of carbon dioxide, CO₂ at various pressures.

FIG. 13 is a graphical depiction of dynamic viscosity, μ, of carbon dioxide, CO₂.

FIG. 14 is graphical depiction of volumetric heat capacity, Cp=ρ·cₚ, for supercritical CO₂ at various pressures (in MPa), liquid-vapor phase-change, supercritical state, liquid state, and subcritical vapor or gas state for water at ambient conditions.

FIG. 15 is a graphical depiction of a modified phase-diagram depicting an anomalous region, “SC Liquidity” state in the subcritical liquid region, and “Liquidity” and “Gaseous” states in the supercritical region.

FIG. 16 is a graphical depiction of a pressure-temperature diagram depicting subcritical liquid behavior of CO₂—Ar mixture: bubble point curve, dew point curve, critical point (P_{c}, T_{c)}), cricondenbar, P_{cric}, and cricondentherm, T_{cric}.

FIG. 17 is a graphical depiction of a pressure-temperature diagram depicting subcritical liquid behavior of CO₂-R134a mixture, bubble point curve, dew point curve, critical point (P_{c}, T_{c)}), cricondenbar, P_{cric}, and cricondentherm, T_{cric}.

FIG. 18 is a graphical depiction of a pressure-temperature diagram depicting subcritical-supercritical behavior of mixture (10% CO₂ and 90% Ar used here as an example): bubble point curve, dew point curve, critical point (P_{c}, T_{c})), cricondenbar, P_{cric}, (higher than P_{c}) and cricondentherm, Tcric (higher than T_{c}).

FIG. 19 is a graphical depiction of heat capacity, Cₚ=ρ·cₚ, as a function of the composition of CO₂—Ar mixture at 14 MPa: (a) Cricondentherm, T_{cric}, (dash-dot) is very close to the critical temperature, T_{c}, (dash) for 70% CO₂-30% Ar.

FIG. 20 is a graphical depiction of heat capacity, Cₚ=ρ·cₚ, of CO₂—Ar mixture as a function of pressure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques below, including the exemplary designs and implementations illustrated and described herein, but may be modified within the scope of the appended claims along with their full scope of equivalents.

A method to alter the critical temperature and thermophysical properties of a heat transfer fluid, and (b) a thermal energy storage fluid, and (c) the gas being transported via pipeline by mixing one (or more) supercritical fluid(s) as a modifier is provided. The critical temperature of the modifier fluid(s) may be higher or lower than that of the base fluid as per the need to reduce or increase the resulting critical temperature. The fraction of the modifier depends on how high or low resulting critical temperature is needed. These systems and methods disclosed herein will lead to very long-distance pipeline transport of gases, ultra-high rate of heat transfer as well as dissipation of heat at terrestrial, extra-terrestrial, and deep-space conditions, such as desert-like-to tropical-to polar-to space-to lunar environments/conditions. In addition, in many heat transfer applications this method can eliminate the use of chemically-reactive, corrosive, toxic, and/or environmentally damaging fluids. This method would be applicable to a variety of heat exchange devices/systems, including energy conversion systems, power generation, power cycles, refrigeration systems, heat exchangers, cold plates, thermal management platforms for either heating or cooling, or both, etc., in industrial applications ranging from thermal power, nuclear reactors, renewable energy, chemical processing, food processing, aerospace, materials processing, semiconductor manufacturing, thermal management of high heat flux devices, e.g., electronics, computers, and large servers, climate control and comfort, and so on. The systems and methods disclosed herein also present an energy-efficient method for pipeline transport of a fluid (without liquefaction) whose critical temperature is close to or higher than the surrounding/ambient temperature, by mixing a small fraction of low critical temperature fluid.

A working fluid is commonly used in heat exchange devices/systems, including energy conversion systems, power generation, power cycles, refrigeration systems, heat exchangers, cold plates, thermal management platforms, etc., in industrial applications ranging from thermal power, nuclear reactors, renewable energy, chemical processing, food processing, aerospace, materials processing, semiconductor manufacturing, biomedical devices, cooling of high heat flux devices, e.g., electronics, computers, and large servers, climate control and comfort, aero-space platforms, and so on. The working fluid is termed as the “heat transfer fluid (HTF)” when it is utilized to transfer thermal energy (heat) in real-time from one location to another, e.g., from higher temperature to lower temperature conditions. The working fluid is also called as the “thermal energy storage (TES)” fluid when thermal energy is intermittently delivered or extracted from the same mass of fluid at a given instant. In certain applications, a working fluid can be utilized simultaneously as HTF and TES fluid. It is envisioned that in many of the above-mentioned applications, the pressure and temperature requirements would be changing intermittently in order to achieve much higher rate of heat transfer and greater efficiency, e.g., depending on the environmental conditions and/or temperature at which the heat is dissipated. This has led to the search of fluids that have highly desirable thermophysical properties such as high heat capacity, high thermal diffusivity, low viscosity, etc. In many applications, the change of phase, particularly liquid to-vapor and/or vapor-to-liquid, is also used to enhance the heat exchange even though phase-change is always associated with issues like, critical heat flux (CHF), burn-out, and reduction in local heat transfer rate.

In addition, many of these systems require dissipation of heat to the surrounding, ambient, or another fluid. Consequently, the working temperature of the fluid by which heat is dissipated becomes a factor in operability. A good example is a system that is capable of rejecting heat to the surrounding in a tropical environment (15-30° C.). If this system is taken to a desert (about 45-50° C.), it may not function effectively or not at all. On the other hand, if this system is used at very low temperatures, such as in cold or polar regions (below 0° C. and cryogenic temperatures), the heat transfer fluid, as for example, water may freeze unless its freezing temperature is reduced by a chemical additive. In essence, precise and controlled heat rejection is severely challenged by the temperature of the fluid to which the heat is rejected.

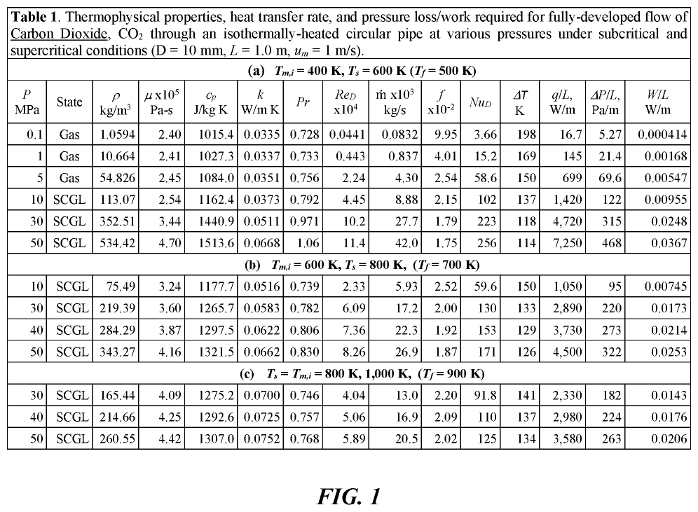

It is well-established that the rate of convective heat transfer increases significantly as the working pressure is increased and the fluid moves from its gaseous state to supercritical “gas-like” (SCG) state. Indeed, a two to three orders-of-magnitude enhancement as compared to heat transfer at atmospheric pressure is possible if the supercritical (SC) pressure becomes high, as depicted in Table 1, of FIG. 1. For example, in the case of CO₂ the heat transfer rate for a fully-developed convective flow through an isothermally heated duct increases from 16.7 watt per meter (W/m) to 1,420 W/m when the pressure increases from 0.1 mega-Paschal (MPa) (near ambient pressure) to 10 MPa and then to 7,250 W/m at 50 MPa. Indeed, this increase in heat transfer can be achieved without phase-change as in the case of systems that involve boiling and/or condensation. Moreover, the increase in pressure loss and pumping power required to achieve the SC conditions and higher rates of heat transfer do not increase significantly.

The working temperature, on the other hand, has an opposite effect. The lower the working temperature, the larger is the increase in heat transfer, by comparing parts (a) and (b) of Table 1 in FIG. 1. This phenomenon of enhancement in heat transfer with increase in pressure and/or decrease in temperature is universal. Indeed, it is directly related to the increases in density and specific heat with increasing pressure and decreasing temperature; the effects of other properties are smaller but still important.

It is therefore possible to select a fluid that can yield a high rate of heat transfer under supercritical conditions. However, this fluid may not be a desirable solution if its critical pressure is very high that would require much higher level of system complexity. On the other hand, if the critical temperature of the fluid is higher than the desired dissipation temperature, this fluid cannot be useful. Such constraints can be demonstrated by examining three fluids: water, carbon dioxide (CO₂), and argon (Ar). For given SC working pressure and temperature, SC water will yield highest rate of heat transfer than SC CO₂; SC Ar will have the lowest values among the three. However, the high critical pressure of water and CO₂, 22.064 MPa (217.8 atm) and 7.377 MPa (72.8 atm), respectively, may not be desirable in all applications. In that case Ar with a critical pressure P_{c}=4.863 MPa can be preferred. On the contrary, if we need to use the fluid at a low temperature (lower than the ambient), water and CO₂ with critical temperatures of 373.95° C. and 30.98° C., respectively, may not be the right choices whereas Ar with a critical temperature of T_{c}=−122.463° C. can serve the purpose. It has been demonstrated that by increasing the mass flow rate and work required (increased by a small amount), a SC fluid such as CO₂ or Ar with lower critical pressure and critical temperature can match the heat transfer by SC water. Similarly, Ar can match the heat transfer rate of CO₂.

Evidently, in applications where a supercritical fluid can be used to dissipate heat, the constraint is not only imposed by its critical temperature but also, by the anomalous region in which thermophysical properties of the fluid change substantially (as discussed hereinafter). It may therefore be desirable in many applications, to use the fluid only under supercritical “gaseous” conditions (SCG) where the thermophysical properties show monotonic trends and variations with pressure and temperature are not large. This implies that the entire range of working pressure and temperature, from heating to cooling, must be sufficiently higher than the critical pressure and temperature. The easiest approach may be to select a fluid with lower critical temperature to avoid such a situation, e.g., falling into anomalous region. Generally, this choice may again be limited by the fluid's critical point and its properties besides the chemical reactivity, toxicity, and environmental concern.

Gas transport under supercritical conditions can be a common practice to transport a gas in its liquified form as the volume of the liquid is substantially lower (density being higher) than that in its gaseous phase; liquid nitrogen and liquefied natural gas (LNG) can be two very common examples. However, there is a clear advantage in transporting fluids under supercritical conditions as it can save on (a) energy required for liquefaction as it would not be needed, (b) cooling stations, which can be needed in the case of, e.g., pipeline delivery, to re-cool the liquid after a certain distance when it becomes warmer and comes closer to the boiling point, would not be needed, and (c) the pressure loss and work required per unit volume can be much lower than that in its liquid state as the dynamic viscosity under SC conditions is significantly lower than that in its liquid state.

However, the pipeline transport of a gas under supercritical condition cannot work if at any location during the transport, the surrounding temperature around the pipeline is close to T_{c}, or lower. For example, it is being proposed to capture, transport (under supercritical conditions), and store ambient and industrially-produced carbon dioxide to meet the carbon capture and storage (CCS) goals. For the SC CO₂ transport, the surrounding temperature can be over its T_{c}(=30.98° C.) from the inlet to the exit of the pipeline, a condition that may not be met if the pipeline is buried underground (temperature being lower than the ambient temperature) and/or passes through a body of water, including ocean. Indeed, this condition cannot be met even on-the-ground on most of the earth's surface; the exception being some very hot regions.

A method to alter the critical temperature of (a) heat transfer fluid, (b) thermal energy storage fluid, and (c) the gas being transported via pipeline (the base fluid) by mixing one (or more) supercritical fluid(s) as a modifier is disclosed herein. The critical temperature of the modifier fluid(s) may be higher or lower than that of the base fluid as per the requirement to reduce or increase the resulting critical temperature. The fraction of the modifier depends on how high or low the resulting T_{c} is required. The disclosed processes and systems will therefore allow to the dissipation of heat at desert-like-to tropical-to polar-to space-to lunar or Martian conditions. Moreover, in many heat transfer applications, this method can eliminate the use of chemically-reactive, corrosive, toxic, and/or environmentally damaging fluids. The systems and methods disclosed herein also present a simple method for pipeline transport of a gas whose critical temperature is close to or higher than the surrounding/ambient temperature; by mixing a small fraction of low critical temperature fluid.

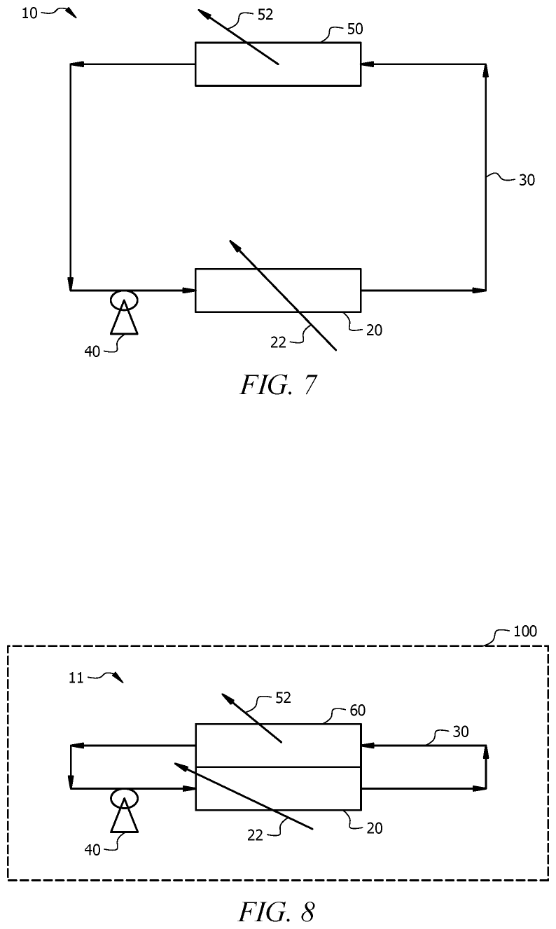

Referring to FIGS. 7-10, in some embodiments, various heat transfer systems are depicted. Referring to FIG. 7, a system 10 can include a heat exchanger 20 receiving a stream 22, a heat dissipater 50, and a fluid transfer device 40, such as a pump 40 or a compressor 40. The heat exchanger 20 can be a shell and tube exchanger, a micro shell and tube exchanger, a plate fin exchanger, or a printed circuit heat exchanger. A working fluid 30 can be pumped by the fluid transfer device 40 to gain heat from one zone, i.e., the heat exchanger 20 from the stream 22, and dissipate that heat as a wave 52 to ambient, such as another medium, at another zone, such as the heat dissipater 50. The working fluid 30 can include two or more supercritical fluids in a supercritical gaseous state. Typically, the supercritical fluids can include helium, hydrogen, neon, nitrogen, carbon dioxide, carbon monoxide, fluorine, air, argon, oxygen, methane, krypton, xenon, 1,1,1,2-tetrafluoroethane or otherwise known as a refrigerant R134a, or any combination thereof. The heat exchange process may include the first supercritical fluid having carbon dioxide and the second supercritical fluid having neon, helium, argon, or a combination thereof. The heat exchange process can include the first supercritical fluid having carbon dioxide or carbon monoxide and the second supercritical fluid having argon. Moreover, the heat exchange process may have the first supercritical fluid including carbon dioxide and the second supercritical fluid including 1,1,1,2-tetrafluoroethane.

In some embodiments, the mixtures of supercritical fluids can be any suitable mixture based on volume. As an example, the first supercritical fluid may be about 1%, about 10%, about 20%, about 30%, about 40%, about 50%, about 60%, about 70%, about 80%, about 90%, or about 99%, by volume, and the second supercritical fluid may be about 1%, about 10%, about 20%, about 30%, about 40%, about 50%, about 60%, about 70%, about 80%, about 90%, or about 99%, by volume. In some embodiments, the first supercritical fluid argon and the second supercritical fluid may be about 90%/about 10%, about 70%/about 30%, about 50%/about 50%, about 40%/about 60%, about 30%/about 70%, about 20%/about 80%, or about 10%/about 90%, by volume, argon/carbon dioxide. In some embodiments, the first supercritical fluid 1,1,1,2-tetrafluoroethane and the second supercritical fluid carbon dioxide may be about 80%/about 20%, about 60%/about 40%, about 40%/about 60%, or about 20%/about 80%, by volume, 1,1,1,2-tetrafluoroethane/carbon dioxide.

Generally, the supercritical fluids are above the critical pressure, the critical temperature, the cricondenbar, and the cricondentherm. Often, the supercritical fluids may have a pressure, P, of at least about 6 MPa and a temperature, T, of greater than about −30° C.

Referring to FIG. 8, a system 11 can include a heat exchanger 20 receiving a stream 22, a radiation device 60, and a fluid transfer device 40. The heat exchanger 20 and the working fluid 30 can be as described above. The radiation device 60 can be coupled to the heat exchanger 20 and the working fluid 30 can be circulated between the heat exchanger 20 and the radiation device 60 via the fluid transfer device 40. The heat exchanger 20 and the working fluid 30 can be as described above. The working fluid 30 can pass through the heat exchanger 20 to absorb heat from the stream 22 and then to the radiation device 60. The radiation device 60 can radiate heat as a wave 52. The system 11 can be included in or coupled to a device or system 100. The device or system 100 can be a high heat flux device, an additively-manufactured and a 3D-printed system, a cooling system for a thermal management of electronic, a printed circuit board, a computing system, a data storage system, and a large server room, a biomedical device for extracting heat during surgery, a machine tool for removing heat from the machining area to maintain the surface being machined at a desired temperature, an avionic system for rejecting heat outside the airplane from avionics and other instrumentation, and a lunar surface system for dissipating heat due to exposure of day and night temperatures on the moon.

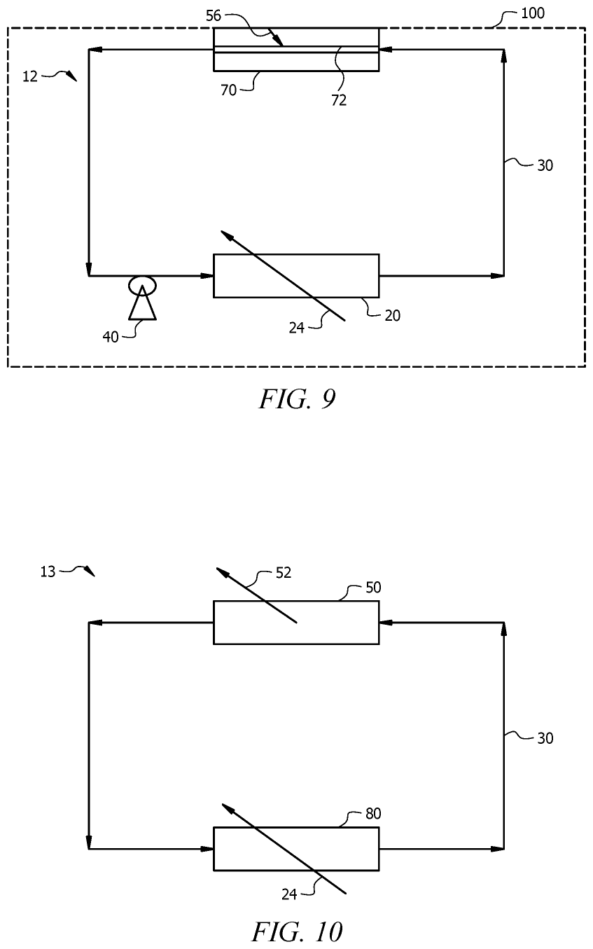

Referring to FIG. 9, a system 12 can include a heat exchanger 20 receiving a cooling stream 24, including a refrigerant, and a cold plate 70 forming a channel 72. The heat exchanger 20 and the working fluid 30 can be the same as described above. The cold plate 70 can extract heat in the form of radiation 56 from a high heat flux device 100. The channel 72 can receive the working fluid 30 to absorb heat from a medium, such as, a cooling system for a thermal management of electronic, a printed circuit board, a computing system, a data storage system, or a large server room. A high heat flux device 100 can emit heat that can be absorbed by the cold plate 70. The working fluid 30 can remove the heat before being transferred to the heat exchanger 20. The working fluid 30 can be as described above. The cooling stream 24 can pass through the heat exchanger 20 to cool the working fluid 30 after exiting the cold plate 70 and the discharge of the fluid transfer device 40.

Referring to FIG. 10, a system 13 can include the heat dissipater 50, a cooler 80, and the working fluid 30. The cooler 80 can receive the cooling stream 24, as described above, to cool the working fluid 30, as described above. The heat dissipater 50 can emit heat as waves 52 from the working fluid 30. The working fluid 30 can return without a fluid transfer device to the cooler 80.

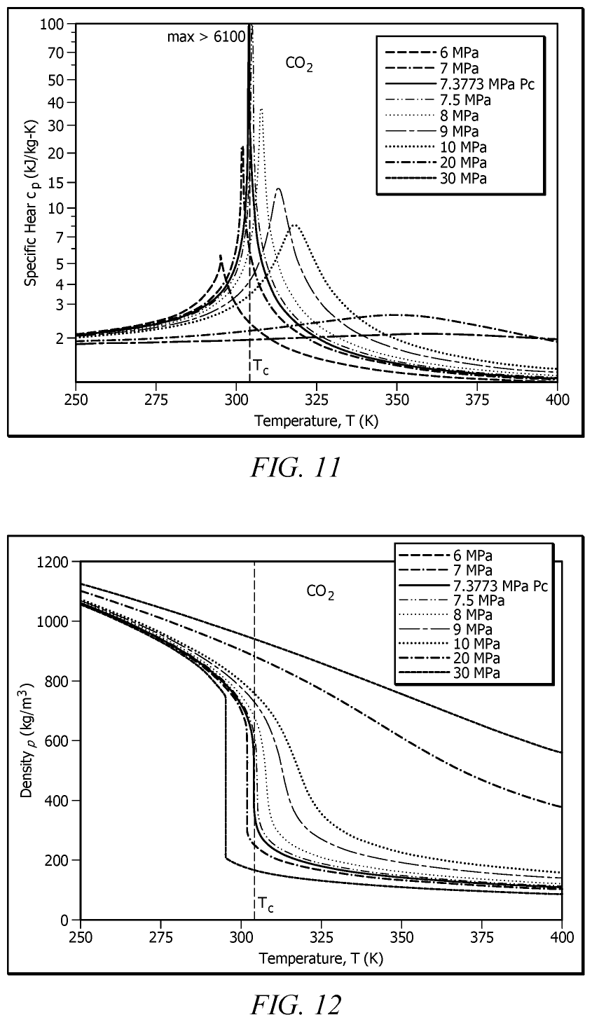

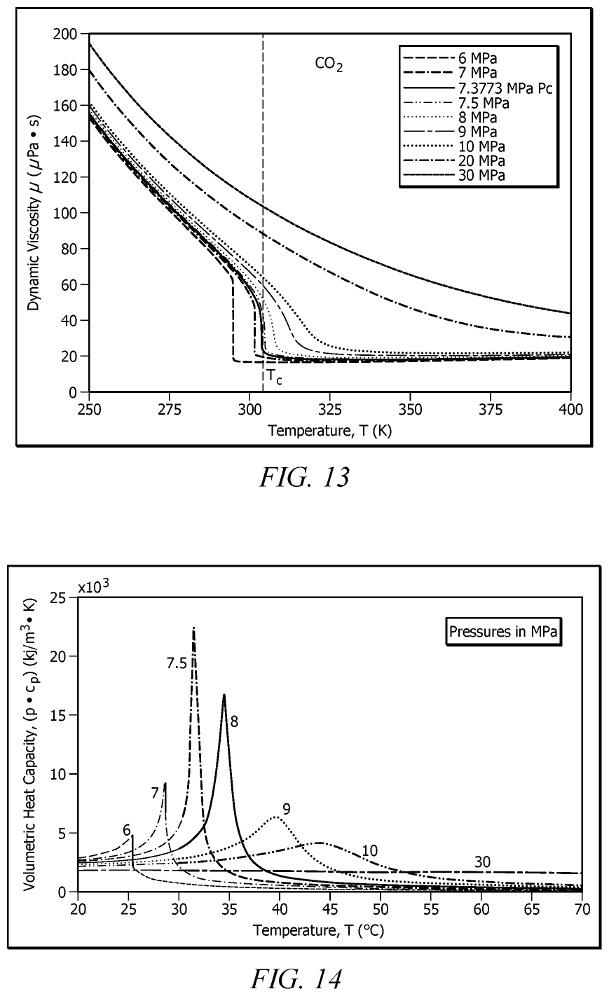

Supercritical fluids demonstrate that the specific heat, cₚ, of CO₂ (P_{c}=7.38 MPa and T_{c}=304.13 K, 30.98° C.) for a given pressure in a region close to the critical pressure, P_{c}, first increases with temperature, achieves a peak value, and then decreases to a monotonic behavior, the peak being highest at the critical point whereas the density, ρ, and dynamic viscosity, μ, exhibit substantial drop in the same region, as depicted in FIG. 11. Note that in this case the heat capacity, (Cₚ=ρcₚ), may be a better parameter to analyze thermal transport in SC fluids because of the simultaneous large changes in both ρ and cₚ. The heat capacity Cₚ as depicted in FIG. 14 shows a similar behavior as cₚ, as depicted in FIG. 11. On the other hand, thermal conductivity (k) follows the trend (not shown here) of μ, as depicted in FIG. 13. As the pressure increases beyond the critical pressure (CP), this behavior of sharp changes is weakened and at high SC pressures, they vanish, as shown by the line of 30 MPa, as depicted in FIGS. 11-14. Also, at high temperatures all properties show monotonic trends irrespective of the SC pressure. This behavior seems to be consistent for all fluids.

To characterize the anomalous behavior of SC fluids near the critical point (CP), a pseudo-critical point was initially described as the temperature at which cₚ had peaks for a given P. Later, the (P, T) line representing the pressure and temperature of the peak values of cₚ under SC conditions (P≥P_{c}) was called the pseudo-critical line. Subsequently, the region in which various fluid properties vary sharply and the fluid behavior is observed to be anomalous was identified as the pseudo-critical region that needed to be treated differently. This anomalous bell curve behavior is exhibited by all fluids.

The initial assumption that complete transformation to SC-state where the liquid and gas are indistinguishable, occurs uniquely at CP has been challenged by many. It has been demonstrated that the SC state should be divided into two regimes—“liquidity” (SCL) and “gaseous” (SCG) states. Recently, it has been convincingly reemphasized that the anomalous behavior, as observed above the critical point, extends to pressures and temperatures much below the CP, and a “SC liquidity” state exists within the subcritical region where sharp changes in the properties can occur. “SC liquidity” state in the subcritical region and “liquidity” state in the SC region may be treated as continuous phases.

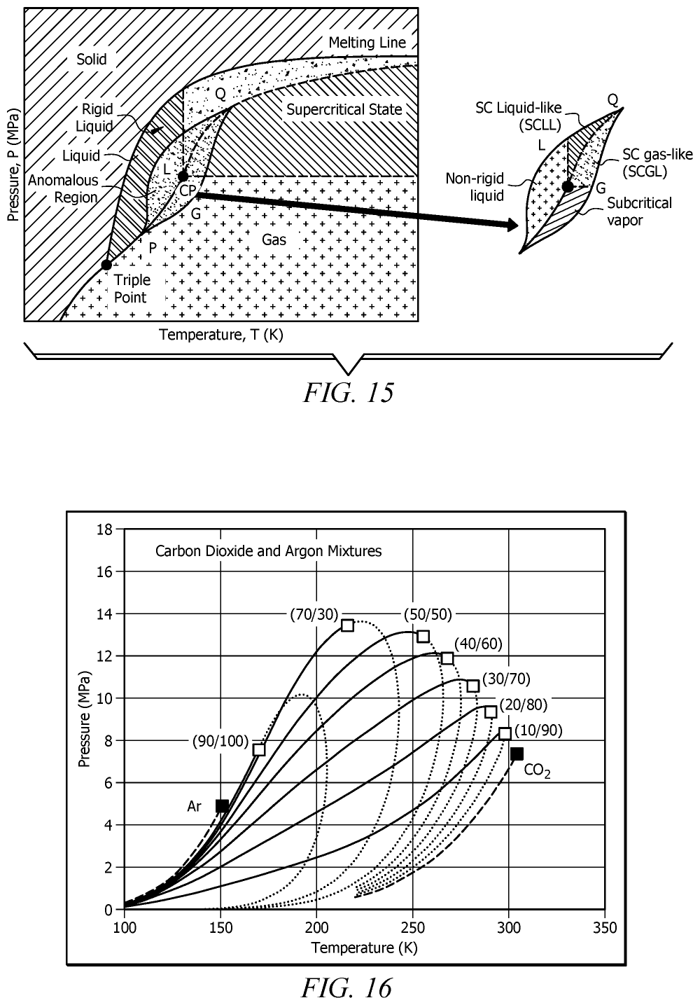

The liquid state therefore needs to be divided into two regions: “regular liquid” as commonly known, and “SC liquidity” where there are anomalous changes. These two regions have also been referred to as the “Rigid Liquid” and Non-rigid Liquid,” as depicted in FIG. 15. The pressure and temperature where “SC liquidity state” begins lies between the triple point and the critical point on a P-T phase diagram, as depicted in FIG. 15. The anomalous region finally ends at a pressure and temperature deep into the SC region. As depicted in FIG. 15, the regular liquid-state exists left of line PLQ, “SC Liquidity” (non-rigid liquid) state starts in the subcritical liquid region right of PLQ, and SC “gaseous” state exists (right of PGQ) in the supercritical region.

In the “SC gaseous” state (right of PGQ labeled supercritical state), where the properties exhibit monotonic trends, existing convection heat transfer correlations may be valid. Evidently, the thermal transport calculations and analysis will be simpler if the transition occurs directly from the subcritical “gaseous” state (hashed area, right bottom) to SC “gaseous” state (labeled supercritical state). It is in this SC gaseous regime that the SC fluids can be transported via pipelines or be used as heat transfer and thermal energy storage fluids to prevent large variations and inversions in thermophysical properties as well as the compressibility effects. The exceptions may be where the goal is to take advantage of the anomalous behavior of the SC fluid.

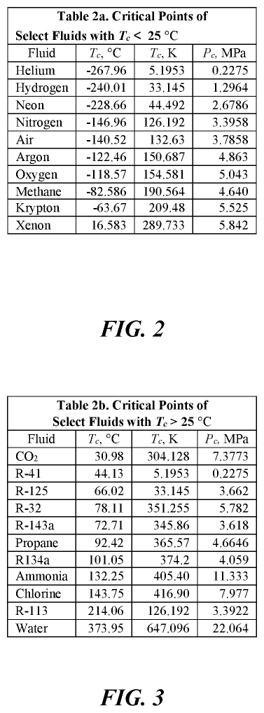

Table 2a as depicted in FIG. 2 presents a select list of SC fluids whose critical temperature is below the ambient temperature and can be suitable as refrigerants under polar, space, and lunar heat transfer conditions although it can be employed for heat dissipation at higher temperatures too. Table 2b as depicted in FIG. 3, on the other hand, lists selected fluids whose critical temperature are near- or above-ambient temperature. These fluids cannot be used as heat transfer fluid at below ambient temperature because of their critical temperature being higher. Also, they cannot be transported via pipeline under supercritical conditions if at any location during the transit they experiences a temperature below the ambient temperature.

Supercritical fluid mixtures can include a desirable fluid (base fluid) that does not meet the requirement of temperature being higher than the critical temperature, T_{c}, to keep it outside the anomalous region and under the SC gaseous state, this fluid can be mixed with another fluid (modifier) with low T_{c} to bring the critical temperature of the mixture down. On the other hand, if there is a need to bring the critical temperature up, a fluid with higher T_{c} can be added. For example, if the T_{c} has to be brought up, a fluid below the base fluid in Tables 2a-2b (with higher T_{c}), as depicted in FIGS. 2-3 can be selected as the modifier fluid, the lower the modifier on this list, the stronger will be the effect and the lower will be the fraction of the modifier fluid. On the contrary, if the T_{c} has to be brought down, a fluid above the base fluid in Tables 2a-2b (with lower T_{c}), as depicted in FIGS. 2-3, can be selected as the modifier fluid. Again, the higher the modifier on this list, the stronger will be the effect and the lower will be the fraction required.

As an illustration, the critical temperature for a mixture of H₂S (9 MPa, 373.1 K) and CH₄ (4.64 MPa, 190.8 K) decreases from the H₂S values as the fraction of CH₄ is increased. The critical temperatures of 0.90CO₂-0.1N₂, and 0.80CO₂-0.20N₂ (by mole fraction) are predicted to be 23.63° C., and 14.55° C., respectively. That means as the fraction of N₂ is increased in SC CO₂—N₂ mixture, T_{c} of the mixture would decrease from T_{c}, CO₂, essentially to the left in FIG. 14. On the other hand, if we need to increase the T_{c} we can mix a fluid of higher critical temperature than that of SC CO₂. Air is the best example to illustrate the increase in T_{c}; it has higher CP than that of N₂ because of O₂, Ar, and CO₂, as depicted in Table 2a of FIG. 3. Similarly, T_{c} for CO₂ increases from 30.98° C. to 111.55° C. and 238.86° C. for 0.9CO₂-0.1C₈H₁₈ and 0.6CO₂-0.4C₈H₁₈, (Carbon dioxide-n-Octane mixture), respectively.

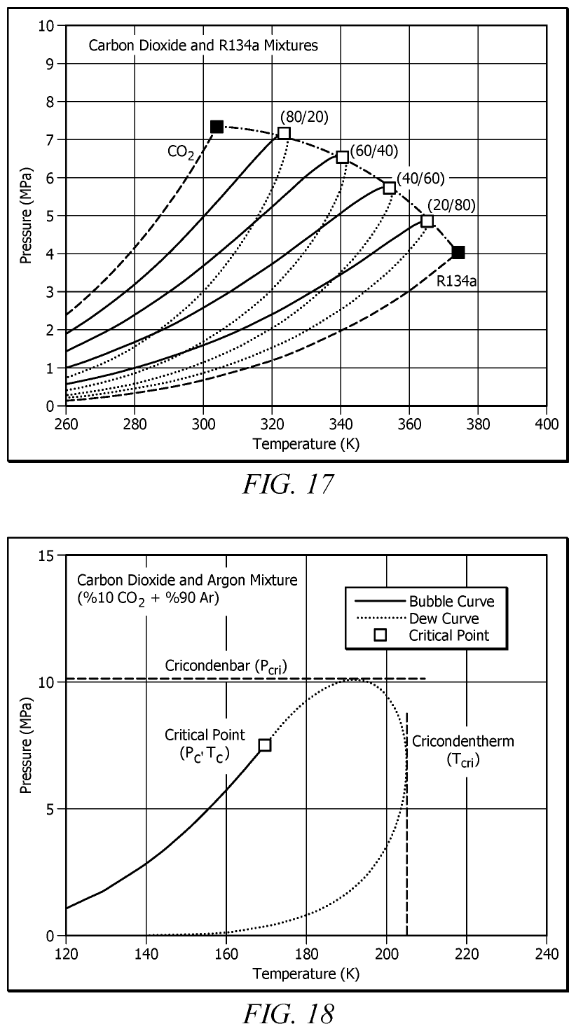

To further demonstrate the phenomenon of change in T_{c}, downward and upward, we have considered here CO₂ as the base fluid and Ar, N₂, and R134a (1,1,1,2-tetrafluoroethane) as the modifiers. FIGS. 16-17 show the P-T curves for bubble point and dew point for CO₂—Ar and CO₂-R134a, respectively, using the Peng-Robinson equations of state. The critical points of single fluid are shown by solid square symbols and that of the mixture by empty square symbols.

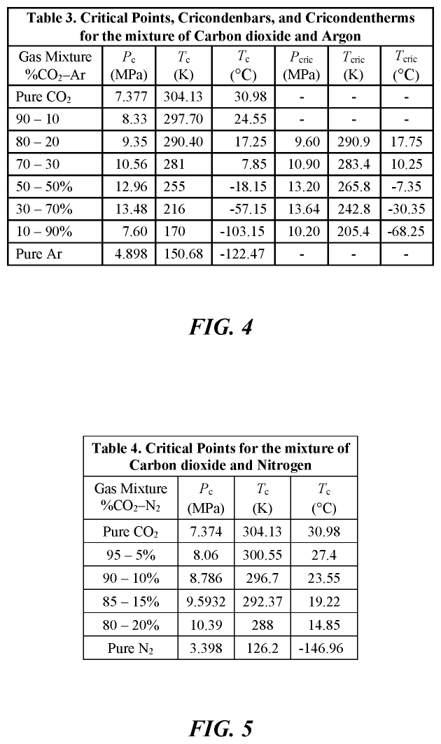

As shown in FIG. 16, the critical temperature of CO₂—Ar mixture decreases as the fraction of Ar is increased, and finally reaches the T_{c} of Ar when it becomes 100%. However, the critical pressure, P_{c} may increase above that of CO₂ and then decrease to that of Ar. This behavior is also demonstrated in Table 3, as depicted in FIG. 4. It is evident that the T_{c} of mixture can be reduced by adding higher mole fraction of Ar; the reduction is smaller at lower fraction of Ar but becomes larger as the percentage of Ar is increased. If the reduction in T_{c} with smaller fraction of Ar is not sufficient, another fluid can be chosen from Table 2a, as depicted in FIG. 2; e.g., N₂ with T_{c}=−146.96° C. As in Table 4, as depicted in FIG. 5, 20% of N₂ brings T_{c} down to 14.85° C. versus 17.75° C. by 20% Ar (Table 3, as depicted in FIG. 4). There are several other fluids that can be considered as modifiers if the goal is to bring the critical temperature further down Table 2a, as depicted in FIG. 2.

Note that if the SC fluid mixture is being used as a heat transfer or thermal energy storage fluid, the properties related to heat capacity and thermal transport become major considerations besides the critical point. However, for gas transport, critical temperature and percentage of the modifier, as small as possible, can become the important criteria.

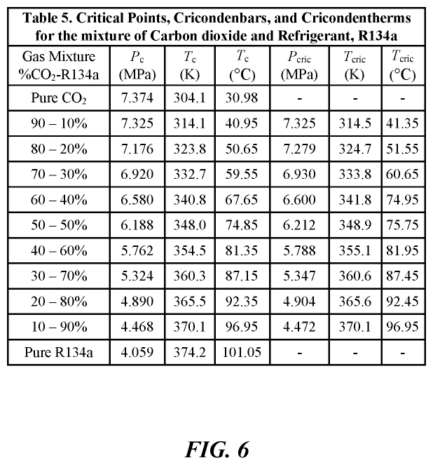

On the other hand, if the goal is to move the critical temperature upward of T_{c}, CO₂, one can pick a fluid below CO₂ in Table 2b, as depicted in FIG. 3. For example, as shown in FIG. 17 and Table 5, as depicted in FIG. 6, for CO₂-R134a mixture the T_{c} of mixture increase from that of CO₂ as the fraction of R134a increases, and finally reaches the T_{c} of R134a when it is 100%. Interestingly, in this case the critical pressure, P_{c} of mixture does not increase, it starts going down gradually with the fraction of R134a, and finally, reaches the P_{c} of R134a.

In FIGS. 16-17, the uppermost point of the curves (on the pressure line) is known as cricondenbar and right extreme point of the curve (on the temperature line) are referred to as the cricondentherm (T_{cric}). The mixture beyond the cricondenbar (P_{cric}) is considered as a dense phase fluid (single phase, may be referred to as “fourth phase”) where it does not experience the dew point and bubble point. In general, the bubble and dew points effect should be avoided to eliminate the possibility of two-phase behavior and thermal instability. Therefore, for the proposed method using a mixture of SC fluids, it would be necessary that the working pressure and temperature are kept above P_{cric} and T_{cric}, respectively. P_{cric} and T_{cric} are observed only in the case of mixtures (not a single fluid). They can be higher, lower, and/or almost equal depending on the constituents of the mixture and their fractions, as depicted in FIG. 18.

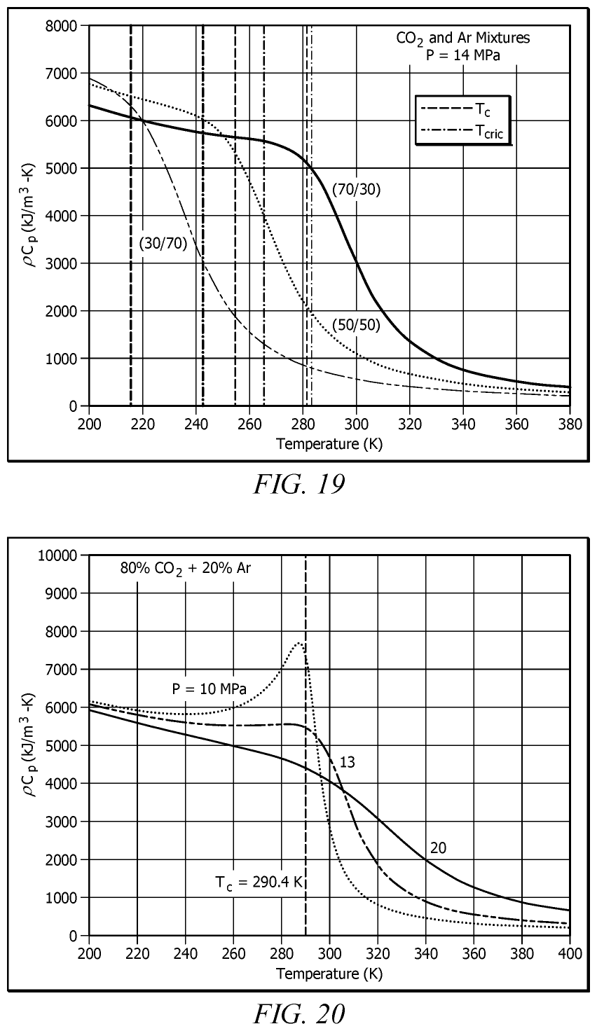

However, cricondentherm temperature and cricondenbar pressure may not guarantee that the (mixture) fluid is in the supercritical “gas-like” state where the thermophysical properties behave monotonically and no large variations in properties occur; a condition necessary for heat transfer and thermal energy storage fluids in most applications and supercritical fluid pipeline transport from varying temperature zones/environments. As shown in FIG. 19, the “safe zone” may be at T greater than 300 K (about 27° C.) for large fraction of CO₂ and below 27° C. for lower percentage for CO₂; evidently, this condition will also depend on pressure as demonstrated in FIG. 20. But they move apart significantly as the mole fraction of Ar increases, see the lines for 30% CO₂-70% Ar, and (b) the conditions at which the anomalous behavior and large-scale variations in thermophysical properties would be absent are far away from both T_{cric} and T_{c}, possibly at temperature higher than 300 K (about 27° C.). Indeed, the higher is the mole fraction of Ar earlier, in terms of temperature, the anomalous behavior ends (compare 30/70 with 70/30). Evidently, the pressure has a strong influence on where the region of no anomalous effect and no large-scale property variations, e.g., SCG state, starts, as depicted in FIG. 20.

That means a judicious choice needs to be made to select a desired critical temperature, e.g., the mole fractions of the mixture components, based on the range of operational pressure and temperature.

Furthermore, the miscibility and reactivity of the fluids to be mixed can be carefully examined. As reported, the miscible binary mixtures are analogous to a pure fluid and the SC state is characterized by a single liquid-vapor transition. Another question to be answered is “Is the theory of miscibility of gases is valid at supercritical gaseous (SCG) conditions?” The answer is yes as long as the fluids are miscible in normal conditions. These mixtures, depending upon the composition of the mixture are expected to display critical temperatures that are in between the T_{c} of the pure fluids, while their critical pressure may pass through a maximum as also shown in FIG. 16.

The base fluid CO₂ is taken as an example, particularly because its T_{c} is near the ambient temperature and it may be the best choice for cooling temperature in the range of 10-50° C. when mixed with a modifier like Ar or N₂; provided they do not react with and/or corrode the system material(s). neon, and xenon Table 2a, as depicted in FIG. 2, although not easily available and expensive, may be other desirable modifiers or base fluid for low temperature applications in upper-end, closed-system applications. On the higher side, for instance, T greater than 30° C., there are several choices from among refrigerants, ammonia, and chlorine in Table 2b, as depicted in FIG. 3.

Indeed, the proposed flexibility of customized mixture to achieve cooling at any temperature and for desired rates of heat transfer can have enormous implications on heat dissipation even under extreme conditions, such as in the polar regions, space, and lunar surface. Indeed, it would be possible to bring the working (cooling) temperature down to 50 K (−223° C.) or even 10 K (−263° C.) by adding neon or helium and increasing its fraction; and at very high temperature conditions, even above 125° C. Note that a noble fluid such as argon may be a better choice as a base fluid at low temperatures since it is non-reacting, non-corroding, non-flammable, and non-toxic and when mixed with other noble fluids, e.g., Ne or He, will be highly compatible. These fluid mixtures will also have a great advantage of being able to work for large range of ultra-low to ultra-high working temperatures.

In addition, it has never been reported that a fluid can be transported at supercritical conditions via a pipeline through the regions of ambient/surrounding temperatures near (on the higher side) or below its critical temperature by using a modifier fluid that can change its critical temperature.

Furthermore, the operational pressure and temperature beyond cricondenbar and cricondentherm, and obviously beyond the critical point, may be a necessary condition for SC gas transport and HTF/TES fluids using mixture but is not a sufficient condition. Indeed, the operational conditions need to be far beyond both the critical point (P_{c}, T_{c}) and Criconden conditions (P_{cric}, T_{cric}) to avoid thermal instability and high level of compressibility

Additional advantages may be apparent to one of skill in the art viewing this disclosure.

Having described various systems and methods herein, certain embodiments can include, but are not limited to:

In a first aspect, a heat exchange process comprises: exchanging heat using a working fluid, wherein the working fluid comprises a mixture of two or more supercritical fluids; and the mixture adapted to meet requirements of a heat dissipation temperature from extremely low to very high temperatures.

A second aspect can include the heat exchange process of the first aspect, wherein the two or more supercritical fluids are in a supercritical gaseous state.

A third aspect can include the heat exchange process of the first or second aspect, wherein the two or more supercritical fluids have a critical temperature below about 25° C.

A fourth aspect can include the heat exchange process of any of the preceding aspects, wherein the two or more supercritical fluids comprise helium, hydrogen, neon, nitrogen, carbon dioxide, carbon monoxide, fluorine, air, argon, oxygen, methane, krypton, xenon, 1,1,1,2-tetrafluoroethane, or any combination thereof.

A fifth aspect can include the heat exchange process of any of the preceding aspects, wherein the two or more supercritical fluids comprise a first supercritical fluid and a second supercritical fluid, and the first supercritical fluid comprises carbon dioxide and the second supercritical fluid comprises neon, helium, argon, or a combination thereof.

A sixth aspect can include the heat exchange process of any of the preceding aspects, wherein the two or more supercritical fluids comprise a first supercritical fluid and a second supercritical fluid, and the first supercritical fluid comprises carbon dioxide or carbon monoxide and the second supercritical fluid comprises argon.

A seventh aspect can include the heat exchange process of any of the preceding aspects, wherein the two or more supercritical fluids comprise a first supercritical fluid and a second supercritical fluid, and the first supercritical fluid comprises carbon dioxide and the second supercritical fluid comprises 1,1,1,2-tetrafluoroethane.

An eighth aspect can include the heat exchange process of any of the preceding aspects, wherein the two or more supercritical fluids comprise a first supercritical fluid and a second supercritical fluid, and the first supercritical fluid comprises carbon dioxide and the second supercritical fluid comprises nitrogen.

A ninth aspect can include the heat exchange process of any of the preceding aspects, further comprising circulating the working fluid.

A tenth aspect can include the heat exchange process of any of the preceding aspects, wherein the two or more supercritical fluids are above a critical pressure, a critical temperature, a cricondenbar, and a cricondentherm of the two or more supercritical fluids.

An eleventh aspect can include the heat exchange process of any of the preceding aspects, wherein the two or more supercritical fluids have a pressure, P of at least about 6 MPa and a temperature and T of greater than about −30° C.

A twelfth aspect can include the heat exchange process of any of the preceding aspects, wherein the extremely low temperature is about 5 K and the very high temperature is about 373 K.

A thirteenth aspect can include the heat exchange process of any of the preceding aspects, wherein the first supercritical fluid is about 1%, about 10%, about 20%, about 30%, about 40%, about 50%, about 60%, about 70%, about 80%, about 90%, or about 99%, by volume, and the second supercritical fluid is about 1%, about 10%, about 20%, about 30%, about 40%, about 50%, about 60%, about 70%, about 80%, about 90%, or about 99%, by volume.

In a fourteenth aspect, a system comprises: heat exchanger, wherein a working fluid is circulated in a pumped loop to gain heat from one zone and to dissipate that heat to ambient, wherein the working fluid is a mixture of supercritical fluids.

A fifteenth aspect can include the system of the fourteenth aspect, further comprising a radiation device coupled to the heat exchanger and a working fluid circulated between the heat exchanger and the radiation device.

A sixteenth aspect can include the system of the fourteenth aspect or the fifteenth aspect, further comprising a cold plate to extract heat from high heat flux devices, wherein the cold plate further comprises a channel for circulating the working fluid.

A seventeenth aspect can include an additively-manufactured and a 3D-printed system comprising the system of the fourteenth aspect.

An eighteenth aspect can include a cooling system for a thermal management of electronic, a printed circuit board, a computing system, a data storage system, and a large server room, wherein the working fluid is a mixture of supercritical fluids, comprising the system of the fourteenth aspect.

A nineteenth aspect can include a biomedical device the system of the fourteenth aspect, where heat needs to be extracted or added, typically using an open flow system or a closed flow loop (or a combination of open and closed flow platforms) to meet the temperature constraints of the particular application, wherein the working fluid is a mixture of supercritical fluids.

A twentieth aspect can include a manufacturing tool: where heat needs to be removed from a specific zone to maintain a desired temperature, wherein the working fluid is a mixture of supercritical fluids, such as for keeping the surface being machined at a desired temperature or the cutting tool at a desired temperature. Alternative embodiments can include applications in welding where the surfaces to be welded can be cooled using supercritical fluids (or mixtures), such as in deep sea operations typically encountered in oil and gas operations, comprising the system of the fourteenth aspect.

A twenty first aspect can include the system of the fourteenth aspect, wherein the supercritical fluids comprise helium, hydrogen, neon, nitrogen, carbon dioxide, carbon monoxide, fluorine, air, argon, oxygen, methane, krypton, xenon, 1,1,1,2-tetrafluoroethane, or any combination thereof.

A twenty second aspect can include the system of the fourteenth aspect or the twenty first aspect, wherein the supercritical fluids are above a critical pressure, a critical temperature, a cricondenbar, and a cricondentherm of the two or more supercritical fluids.

A twenty third aspect can include the system of the fourteenth aspect, the twenty first aspect, or a twenty second aspect, wherein the supercritical fluids have a pressure, P, of at least about 6 MPa and a temperature, T, of greater than about −30° C.

A twenty fourth aspect can include an avionic system for rejecting heat outside an airplane from avionics and other instrumentation, comprising the system of the fourteenth aspect.

A twenty fifth aspect can include satellites and space station for reject heat by radiation to space, comprising the system of the fourteenth aspect.

A twenty sixth aspect can include a lunar or Martian surface system for dissipating heat due to exposure of day and night temperatures on the moon or where a heat exchanger is used for energy conversion, wherein the working fluid is a mixture of supercritical fluids; these fluids may be available on the moon or Mars itself, comprising the system of the fourteenth aspect.

In a twenty seventh aspect, a system comprises: a heat exchanger to dissipate heat to ambient, wherein a working fluid is circulated without pumping between the heat exchanger and a cooling component exposed to the ambient, wherein the working fluid is a mixture of supercritical fluids.

In a twenty eighth aspect, a heat exchange process comprises: exchanging heat using a working fluid, wherein the working fluid is a mixture of two or more supercritical fluids; the mixture specially prepared to meet the requirement of the temperature at which the heat needs to be dissipated, applicable to from extremely low to very high temperatures.

In a twenty ninth aspect, an energy conversion system wherein the working fluid is a mixture of two or more supercritical fluids; wherein the mixture is specially prepared to meet the requirement of the hot and cold temperatures of the energy conversion process.

In a thirtieth aspect, a system comprises: a heat exchanger where a working fluid is circulated in a pumped loop to gain heat from one location, one area, or one zone and dissipate that heat to ambient, a surrounding, or another medium, wherein the working fluid is a mixture of supercritical fluids.

In a thirty first aspect, a system comprises: a heat exchanger; a radiation device coupled to the heat exchanger and a working fluid circulated between the heat exchanger and the radiation device, wherein the working fluid is a mixture of supercritical fluids.

In a thirty second aspect, a system comprises: a heat exchanger; in which working fluid is circulated between the heat exchanger and dissipated to a space or ambient by radiation device, wherein the working fluid is a mixture of supercritical fluids.

In a thirty third aspect, a cold plate to extract heat from high heat flux devices comprises: a flow channel of macro, micro, and nano size; a working fluid circulated through this channel, wherein the working fluid is a mixture of supercritical fluids.

In a thirty fourth aspect, a cooling system can be used for thermal management of electronics, printed circuit boards, computing systems, data storage systems, and large server rooms.

In a thirty fifth aspect, a biomedical device; where heat needs to be extracted during surgery using a flow loop, wherein the working fluid is a mixture of supercritical fluids to meet the temperature constraint of the human body.

In a thirty sixth aspect, a machine tool comprises a configuration where heat needs to be removed from the machining area to maintain the surface being machined at a desired temperature, wherein the working fluid is a mixture of supercritical fluids.

In a thirty seventh aspect, a machine tool comprises a configuration where heat needs to be removed to cool a cutting, a sawing, or a drilling tool at a desired temperature, wherein the working fluid is a mixture of supercritical fluids.

In a thirty eighth aspect, an additively-manufactured and a 3D-printed system comprises: a heat exchanger with a macro, a micro, and a nano-channel for heat transfer fluid flow, wherein the working fluid is a mixture of supercritical fluids.

In a thirty ninth aspect, a passive system (without pumped flow loop) comprises: a heat exchanger to dissipate heat to the ambient, surrounding or another medium; a working fluid circulated between the heat exchanger and the cooling component exposed to ambient, wherein the working fluid is a mixture of supercritical fluids.

In a fortieth aspect, an avionic system comprises a configuration where a heat exchanger is used to reject heat from avionics and other instrumentation to cold air outside the airplane, wherein the working fluid is a mixture of supercritical fluids.

In a forty first aspect, a space system, including satellites and space station, comprises a configuration where a heat exchanger is used to reject heat by radiation to space, wherein the working fluid is a mixture of supercritical fluids.

In a forty second aspect, a space vehicle comprises a configuration where heat needs to be removed and rejected into space, wherein the working fluid is a mixture of supercritical fluids.

In a forty third aspect, a lunar surface system exposed to day and night temperatures on the moon comprises a configuration where a heat exchanger is used to dissipate heat, wherein the working fluid is a mixture of supercritical fluids.

In a forty fourth aspect, a lunar surface energy conversion system exposed to day and night temperatures on the moon comprises a configuration where a heat exchanger is used for energy conversion, wherein the working fluid is a mixture of supercritical fluids; these fluids may be available on the moon itself.

In a forty fifth aspect, a pipeline gas transport system working under supercritical conditions comprises a configuration where a modifier gas is added to meet the temperature constraints because of the surrounding/ambient through which the pipeline passes.

For purposes of the disclosure herein, the term “comprising” includes “consisting” or “consisting essentially of.” Further, for purposes of the disclosure herein, the term “including” includes “comprising,” “consisting,” or “consisting essentially of.”

Accordingly, the scope of protection is not limited by the description set out above but is only limited by the claims which follow, that scope including all equivalents of the subject matter of the claims. Each and every claim is incorporated into the specification as an embodiment of the present invention. Thus, the claims are a further description and are an addition to the embodiments of the present invention. The discussion of a reference in the Description of Related Art is not an admission that it is prior art to the present invention, especially any reference that may have a publication date after the priority date of this application. The disclosures of all patents, patent applications, and publications cited herein are hereby incorporated by reference, to the extent that they provide exemplary, procedural or other details supplementary to those set forth herein.

While embodiments of the invention have been shown and described, modifications thereof can be made by one skilled in the art without departing from the spirit and teachings of the invention. The embodiments described herein are exemplary only, and are not intended to be limiting. Many variations and modifications of the invention disclosed herein are possible and are within the scope of the invention. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, R_{L}, and an upper limit, R_{U}, is disclosed, any number falling within the range is specifically disclosed. In particular, the following numbers within the range are specifically disclosed: R=R_{L}+k*(R_{U}−R_{L}), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim is intended to mean that the subject element is required, or alternatively, is not required. Both alternatives are intended to be within the scope of the claim. As used herein, the term “and/or” can mean one, some, or all elements depicted in a list. As an example, “A and/or B” can mean A, B, or a combination of A and B. Use of broader terms such as comprises, includes, having, etc. should be understood to provide support for narrower terms such as consisting of, consisting essentially of, comprised substantially of, etc.

What is claimed is:

1. A heat exchange process comprising:
exchanging heat using a working fluid, wherein the working fluid comprises a mixture of two or more supercritical fluids; and wherein the mixture adapted to meet requirements of a heat dissipation temperature from extremely low to very high temperatures.

2. The heat exchange process of claim 1, wherein the two or more supercritical fluids are in a supercritical gaseous state.

3. The heat exchange process of claim 2, wherein the two or more supercritical fluids have a critical temperature below about 25° C.

4. The heat exchange process of claim 1, wherein the two or more supercritical fluids comprise helium, hydrogen, neon, nitrogen, carbon dioxide, carbon monoxide, fluorine, air, argon, oxygen, methane, krypton, xenon, 1,1,1,2-tetrafluoroethane, or any combination thereof.

5. The heat exchange process of claim 1, wherein the two or more supercritical fluids comprise a first supercritical fluid and a second supercritical fluid, and the first supercritical fluid comprises carbon dioxide and the second supercritical fluid comprises neon, helium, argon, or a combination thereof.

6. The heat exchange process of claim 1, wherein the two or more supercritical fluids comprise a first supercritical fluid and a second supercritical fluid, and the first supercritical fluid comprises carbon dioxide or carbon monoxide and the second supercritical fluid comprises argon.

7. The heat exchange process of claim 1, wherein the two or more supercritical fluids comprise a first supercritical fluid and a second supercritical fluid, and the first supercritical fluid comprises carbon dioxide and the second supercritical fluid comprises 1,1,1,2-tetrafluoroethane.

8. The heat exchange process of claim 1, wherein the two or more supercritical fluids comprise a first supercritical fluid and a second supercritical fluid, and the first supercritical fluid comprises carbon dioxide and the second supercritical fluid comprises nitrogen.

9. The heat exchange process of claim 1, wherein the two or more supercritical fluids are above a critical pressure, a critical temperature, a cricondenbar, and a cricondentherm of the two or more supercritical fluids.

10. The heat exchange process of claim 1, wherein the extremely low temperature is about 5 K and the very high temperature is about 373 K.

11. A system comprising:
a heat exchanger;
a working fluid, wherein the working fluid is a mixture of supercritical fluids; and
a pumped loop, wherein the system is configured to circulate the working fluid in the pumped loop to gain heat from one zone and to dissipate the heat to ambient.

12. The system of claim 11, further comprising:
a radiation device coupled to the heat exchanger and the working fluid is circulated between the heat exchanger and the radiation device.

13. The system of claim 11, further comprising:
a cold plate to extract heat from a high heat flux device, wherein the cold plate further comprises a channel for circulating the working fluid.

14. The system of claim 11, wherein the heat exchanger is thermally coupled to a 3D-printed system.

15. The system of claim 11, wherein the heat exchanger is thermally coupled to an electronic device, a biomedical device, a printed circuit board, a computing system, a data storage system, a machining system, a large server room, an aviation system, a space system, a lunar surface system, or a Martian surface system.

16. The system of claim 11, wherein the supercritical fluids comprise helium, hydrogen, neon, nitrogen, carbon dioxide, carbon monoxide, fluorine, air, argon, oxygen, methane, krypton, xenon, 1,1,1,2-tetrafluoroethane, or any combination thereof.

17. The system of claim 11, wherein the supercritical fluids are above a critical pressure, a critical temperature, a cricondenbar, and a cricondentherm of the supercritical fluids.

18. The system of claim 17, wherein the supercritical fluids have a pressure, P, of at least about 6 MPa and a temperature, T, of greater than about −30° C.

19. The system of claim 11, wherein the mixture of supercritical fluids comprises a first supercritical fluid and a second supercritical fluid, and the first supercritical fluid comprises carbon dioxide and the second supercritical fluid comprises neon, helium, argon, or a combination thereof.

20. The system of claim 11, wherein the mixture of supercritical fluids comprises a first supercritical fluid and a second supercritical fluid, and the first supercritical fluid comprises carbon dioxide and the second supercritical fluid comprises 1,1,1,2-tetrafluoroethane.
